(19) United States
(12) Patent Application Publication
(10) Pub. No.: US 2018/0122461 A1
(43) Pub. Date: May 3, 2018

(54) RESISTIVE MEMORY APPARATUS

(71) Applicant: SK hynix Inc., Icheon-si Gyeonggi-do (KR)

(72) Inventor: Choung Ki SONG, Yongin-si Gyeonggi-do (KR)

(73) Assignee: SK hynix Inc., Icheon-si Gyeonggi-do (KR)

(21) Appl. No.: 15/471,307

(22) Filed: Mar. 28, 2017

(30) Foreign Application Priority Data
Nov. 1, 2016 (KR) 1020160144586

(51) Int. Cl. G11C 13/00

(52) U.S. Cl. CPC G11C 13/004; G11C 13/0069; G11C 13/0038

(57) ABSTRACT

A resistive memory apparatus in accordance with an embodiment may include a memory circuit and a plurality of unit input/output (I/O) circuits. The memory circuit may be divided into a plurality of partitions. Each of the plurality of unit I/O circuits may be provided for each of the plurality of partitions. Each I/O circuit may be disposed where each partition is formed.

### CROSS-REFERENCES TO RELATED APPLICATION

The present application claims priority under 35 U.S.C. § 119(a) to Korean application number 10-2016-0144586 filed on Nov. 1, 2016, in the Korean Intellectual Property Office, which is incorporated herein by reference in its entirety.

### BACKGROUND

### 1. Technical Field

Various embodiments may generally relate to a semiconductor integrated apparatus, and more particularly to a resistive memory apparatus.

### 2. Related Art

A resistive memory apparatus may be a memory apparatus that stores data in a data storage material layer arranged between a pair of electrodes by changing a resistance state of the data storage material layer.

Semiconductor manufacturers are producing highly integrated resistive memory apparatuses, and as a result an amount of current required for operating the resistive memory apparatuses is being increased.

A read/write circuit operating the resistive memory apparatus may be disposed on an edge of a memory region. Accordingly, when write/read operations are performed, a read/write operation time required to read and write from and to a memory cell spaced relatively far away from the read/write circuit.

Since a larger voltage than an actual operating voltage has to be applied to provide the actual operating voltage up to such a memory cell, power consumption may increase.

### SUMMARY

In an embodiment of the present disclosure, a resistive memory apparatus may include a memory circuit and a plurality of unit input/output (I/O) circuits. The memory circuit may be divided into a plurality of partitions. The plurality of I/O circuits provided for each of the plurality of partitions. Each I/O circuit may be disposed where each partition is formed.

In an embodiment of the present disclosure, a resistive memory apparatus may include a memory circuit and a plurality of unit input/output (I/O) circuits. The memory circuit may be divided into a plurality of partitions. The plurality of unit I/O circuits may be electrically coupled to an adjacent partition pair.

These and other features, aspects, and embodiments are described below in the section entitled “DETAILED DESCRIPTION”

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a diagram illustrating an example of a resistive memory apparatus according to an embodiment of the present disclosure;

FIG. 2 is a diagram illustrating an example of a partition and an input/output (I/O) circuit according to an embodiment of the present disclosure;

FIG. 3 is a diagram illustrating an example of a unit I/O circuit according to an embodiment of the present disclosure;

FIG. 4 is a timing diagram explaining an operation of a resistive memory apparatus according to an embodiment of the present disclosure;

FIG. 5 is a diagram illustrating an example of a resistive memory apparatus according to an embodiment of the present disclosure; and

FIGS. 6 to 10 are diagrams illustrating examples of resistive memory cells according to an embodiment of the present disclosure.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

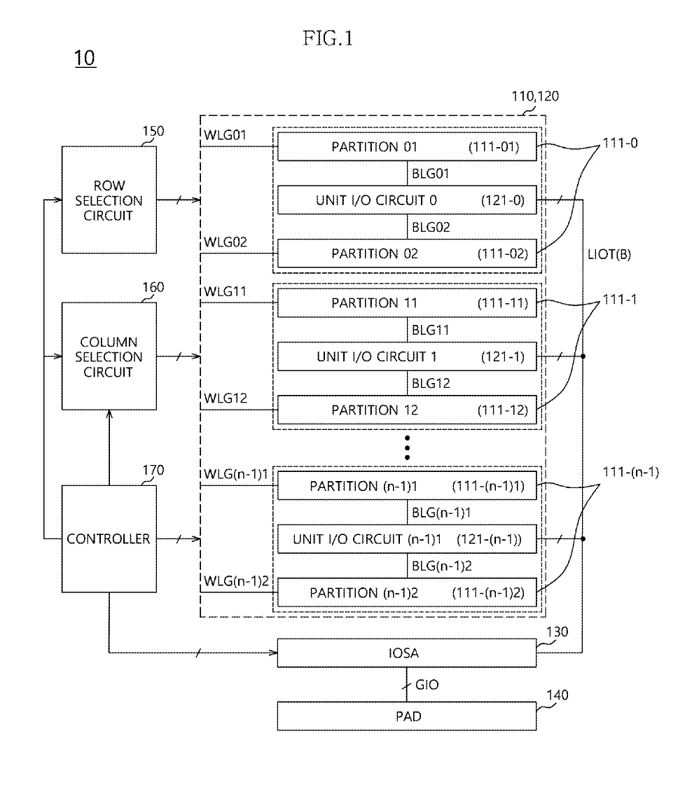

FIG. 1 is a diagram illustrating an example of a resistive memory apparatus according to an embodiment.

Referring to FIG. 1, a resistive memory apparatus 10 according to an embodiment may include a memory circuit 110, an I/O circuit 120, an I/O sense amplifier (IOSA) 130, a pad 140, a row selection circuit 150, a column selection circuit 160, and a controller 170.

The memory circuit 110 may be divided into a plurality of partitions 111-0 to 111-(n-1) which may be collectively referred to as “111.” Each of the partitions 111-0 to 111-(n-1) may be divided into an upper sub-partition 111-x1 and a lower sub-partition 111-x2 (e.g., x is a natural number from 0 to [n−1]).

The partition 111-0 to 111-(n-1) may include a plurality of memory cells arranged on intersection points of word line groups WLG0 to WLG(n-1) including a plurality of word lines and bit line groups BLG0 to BLG(n-1) including a plurality of bit lines.

As the partition 111-0 to 111-(n-1) is divided into the upper sub-partition 111-x1 and the lower sub-partition 111-x2, each of the word line groups WLG0 to WLG(n-1) may be divided into an upper word line group WLG01 to WLG(n-1)1 including at least one word line and a lower word line group WLG02 to WLG(n-1)2 including at least one word line.

The memory cells constituting each of the partitions 111-0 to 111-(n-1) of the memory circuit 110 may be implemented using a memory cell that uses variable resistance changes of a data storage node in storing data. Examples of the memory cells may include a phase-change random access memory (PRAM) cell using a chalcogenide alloy, a magnetic RAM (MRAM) cell using a tunneling magneto-resistive (TMR) effect, a resistive RAM (RERAM) cell using a transition metal oxide, a polymer RAM cell, a RAM cell using perovskite, a ferroelectric RAM (FRAM) cell using a ferroelectric capacitor, and the like, but the memory cells are not limited thereto.

Each of the memory cells constituting the partition 111-0 to 111-(n-1) of the memory circuit 110 may be a single level cell (SLC) which stores one bit of data per one memory cell or a multi-level cell (MLC) which stores two or more bits of data per one memory cell.

The I/O circuit 120 may include a plurality of unit I/O circuits 121-0 to 121-(n-1), which may be collectively referred to as “121.”

The plurality of unit I/O circuits 121-0 to 121-(n-1) may be provided in the partitions 111-0 to 111-(n-1). For example, each of the plurality of unit I/O circuits 121-0 to 121-(n-1) may be provided for each of the plurality of partitions the partitions 111-0 to 111-(n-1), and each I/O circuit 121-0 to 121-(n-1) may be disposed where each partition 111-0 to 111-(n-1) is formed. In an embodiment, each of the plurality of unit I/O circuits 121-1 to 121-(n-1) may be arranged between the upper sub-partition 111-x1 and the lower sub-partition 111-x2 of each partition 111.

As the partition 111 is divided into the upper sub-partition 111-x1 and the lower sub-partition 111-x2, a bit line group extending from the upper sub-partition 111-x1 to the unit I/O circuit 121 may be referred to as an upper bit line group BLGx1 and a bit line group extending from the lower sub-partition 111-x2 to the unit I/O circuit 121 may be referred to as a lower bit line group BLGx2.

The read or write operation may be performed by supplying an operating voltage through the unit I/O circuit 121 provided in a specific partition 111 during the I/O operation session for the specific partition 111.

As compared with the memory circuit that uses a single I/O circuit for all the partitions 111-0 to 111-(n-1), the memory circuit 110 may have an improved read/write operation speed since the power supply and read/write operations are separately performed for each of the partitions 111-0 to 111-(n-1). When the single I/O circuit is used for all the partitions 111-0 to 111-(n-1), a voltage having a higher level than an actual operating voltage is provided to apply the actual operating voltage to a partition located relatively far away from the I/O circuit. However, if the I/O circuits 121 are separately assigned to each partition 111, power consumption may decrease.

The plurality of unit I/O circuits 121-0 to 121-(n-1) may be coupled in common to the I/O sense amplifier 130 through a local I/O line pair LIOT(B).

The I/O sense amplifier 130 may amplify data read from the plurality of unit I/O circuits 121-0 to 121-(n-1) and provide the amplified data to the pad 140 through a global I/O line GIO. The I/O sense amplifier 130 may amplify write data provided from the pad 140 through the global I/O line GIO and provide the amplified write data to the plurality of unit I/O circuits 121-0 to 121-(n-1).

The row selection circuit 150 and the column selection circuit 160 may be address decoders, and may receive address signals. The row selection circuit 150 may receive a row address of a memory cell to be accessed, for example, a word line address and decode the received word line address through control of the controller 170. The column selection circuit 160 may receive a column address of the memory cell to be accessed. For example, the column selection circuit 160 may receive a bit line address and decode the received bit line address in response to control signals of the controller 170.

The controller 170 may control an overall operation of the resistive memory apparatus 10 so that data may be transmitted and received to and from an external device such as a host apparatus (not illustrated) and the resistive memory apparatus 10.

In the read and write operations for the memory circuit 110, the operating voltage may be applied to a selected memory cell of a selected partition 111. Since the unit I/O circuit 121 is separately provided for each partition 111, the read and write operations may be performed on each selected partition 111 at a high speed while consuming a minimum power.

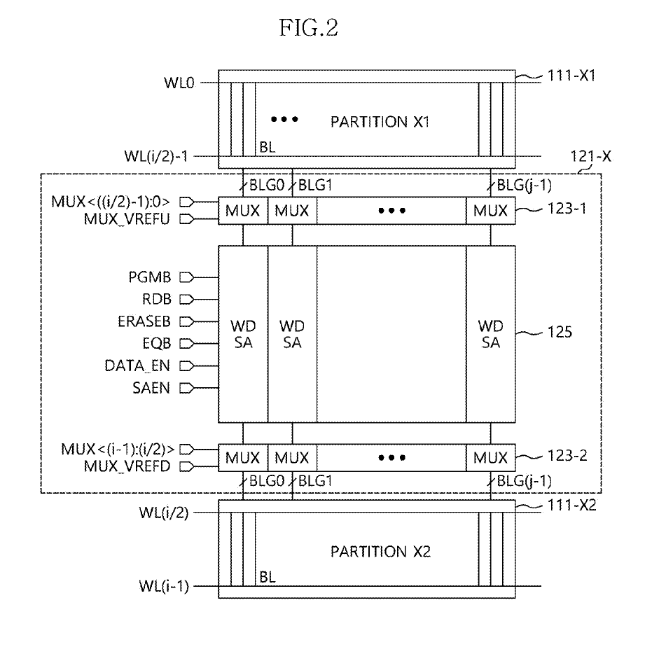

FIG. 2 is a diagram illustrating an example of a partition and an I/O circuit according to an embodiment.

Referring to FIG. 2, the partition 111 according to an embodiment may include the upper sub-partition 111-x1 and the lower sub-partition 111-x2.

The upper sub-partition 111-x1 may include a plurality of memory cells coupled between at least one upper word line WL0 to WL(i/2)-1 (e.g., the upper word line group) and a plurality of bit lines BL (e.g., the upper bit line group BLGx1). The upper bit line group BLGx1 may be subdivided into a plurality of sub bit line groups BLG0 to BLG(j-1).

Similarly, the lower sub-partition 111-x2 may include a plurality of memory cells coupled between at least one lower word line WL(i/2) to WL(i−1) (e.g., the lower word line group) and a plurality of bit lines BL (e.g., the lower bit line group BLGx2). The lower bit line group BLGx2 may be subdivided into a plurality of sub bit line groups BLG0 to BLG(j-1).

The unit I/O circuit 121-x arranged between the upper sub-partition 111-x1 and the lower sub-partition 111-x2 of the partition 111x may include a first selection circuit 123-1, a second selection circuit 123-2, and a read/write circuit 125.

The first selection circuit 123-1 may include a plurality of selection units MUX coupled to the plurality of sub bit line groups BLG0 to BLG(j-1) extending from the upper sub-partition 111-x1. Each of the selection units MUX may select one of bit lines included in a corresponding bit line group BLG0 to BLG(j-1) in response to a selection signal MUX<((i/2)−1):0> and a first reference voltage MUX_VREFU.

The second selection circuit 123-2 may include a plurality of selection units MUX coupled to the plurality of sub bit line groups BLG0 to BLG(j-1) extending from the lower sub-partition 111-x2. Each of the selection units MUX may select one of bit lines included in a corresponding bit line group BLG0 to BLG(j-1) in response to a select signal MUX<(i−1):i/2> and a second reference voltage MUX_VREFD.

The selection unit MUX may be a multiplexer, but the present disclosure is not limited thereto.

The read/write circuit 125 may include a plurality of unit read/write circuits WDSA coupled between the first selection circuit 123-1 and the second selection circuit 123-2.

Each of the unit read/write circuits WDSA may write data in the selected memory cell of the selected partition or read data from the selected memory cell of the selected partition in response to a first write command PGMB, a read command RDB, a second write command ERASEB, an equalization command EQB, a data enable signal DATA_EN, and a sense amplifier enable signal SA_EN.

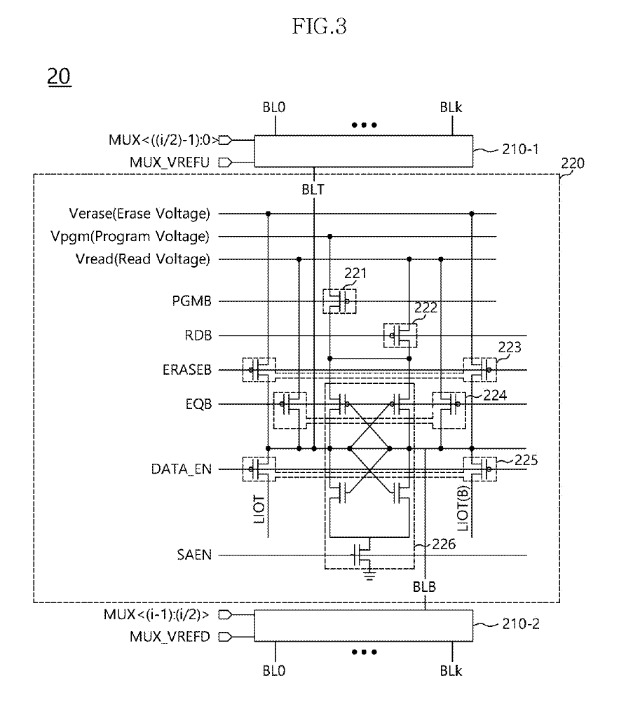

FIG. 3 is a diagram illustrating an example of an I/O circuit according to an embodiment.

Referring to FIG. 3, a unit I/O circuit 20 according to an embodiment may include a first selection circuit 210-1, a second selection circuit 210-2, and a unit read/write circuit 220.

The first selection circuit 210-1 may select one of sub lit line groups BL0 to BLk extending from the upper sub-partition 111-x1 as a select bit line BLT. The second selection unit 210-2 may select one of sub bit line groups BL0 to BLk extending from the lower sub-partition 111-x2 as a complementary bit line BLB.

The unit read/write circuit 220 may be coupled between the select bit line BLT and the complementary bit line BLB.

The unit read/write circuit 220 may include a first write voltage providing circuit 221, a read voltage providing circuit 222, a second write voltage providing circuit 223, an equalization circuit 224, a driving circuit 225, and an amplification circuit 226.

The first write voltage providing circuit 221 may provide a first write voltage Vpgm to the amplification unit 226 in response to the first write command PGMB.

The read voltage providing circuit 222 may provide a read voltage Vread to the select bit line BLT and the complementary bit line BLB in response to the read command RDB.

The second write voltage providing circuit 223 may provide a second write voltage Verase to the select bit line BLT and the complementary bit line BLB in response to the second write command ERASEB.

The equalization circuit 224 may equalize the select bit line BLT and the complementary bit line BLB to a preset level of voltage in response to the equalization command EQB.

The driving circuit 225 may electrically couple or disconnect a bit line pair including the select bit line BLT and the complementary bit line BLB to a local I/O line pair LIOT/LIOTB in response to the data enable signal DATA_EN.

The amplification circuit 226 may be driven in response to the sense amplifier enable signal SAEN, and may amplify voltages applied to the select bit line BLT and the complementary bit line BLB according to a supply voltage.

FIG. 4 is a timing diagram explaining an example of an operation of a resistive memory apparatus according to an embodiment.

A certain word line WL of a certain partition may be selected through the row selection circuit 150 in a second write operation ERASE, a first write operation Program, and a read operation Read (data=1 or 0). One of the upper bit line groups may be selected as the select bit line BLT through the selection signal MUX applied to the first selection circuit (MUX) 210-1, and one of the lower bit line groups may be selected as the complementary bit line BLB through the selection signal MUX applied to the second selection unit (MUX) 210-2.

A preset level of a first reference voltage MUX_VREFU and a preset level of a second reference voltage MUX_VREFD may be applied to the first selection circuit (MUX) 210-1 and the second selection unit (MUX) 210-2.

In the second write operation ERASE, the second write command ERASEB may be enabled, and potentials of the select bit line BLT and the complementary bit line BLB may be boosted up to the second write voltage Verase, and thus second data may be written in the selected memory cell. The amplification circuit 226 may be in a disabled state in the second write operation.

When a large number of memory cells are simultaneously accessed in the second write operation, the second write operation may become unstable because power consumption may reach its peak.

In an embodiment, the second write operation may be sequentially performed on the plurality of bit line groups by sequentially enabling plural bits of selection signals MUX provided to the first selection circuit (MUX) 210-1 and the second selection circuit (MUX) 210-2.

The second write operation may be performed on memory cells coupled to the plurality of bit line groups while the second write voltage Verase is being continuously supplied through the unit I/O circuit 121 and 20. Accordingly, it is possible to avoid undesired power consumption, and it is possible to maintain a stable second write operation.

Even when the upper sub-partition 111-x1 and the lower sub-partition 111-x2 are configured to include the plurality of word lines, the second write operation may be repeatedly performed by sequentially enabling the plural bits of selection signals MUX and by changing only a voltage condition for a word line.

In the first write operation Program, first data having a level of the read voltage Vread may be set at an output terminal of the amplification circuit 226 by enabling the read command RDB. A potential of the output terminal of the amplification circuit 226 may be boosted up to a level of the first write voltage Vpgm by disabling the read command RDB and enabling the second write command PGMB. Accordingly, the voltage level of the first data may be boosted up to the level of the first write voltage Vpgm. The first data boosted up to the level of the first write voltage Vpgm may be written in the selected memory cell.

In the read operation Read, the select bit line BLT and the complementary bit line BLB may be first precharged with the read voltage Vread, and then may be floating. Accordingly, a current may flow through a memory cell, and when the read command RDB and the sense amplifier enable signal SAEN are enabled after a fixed time elapsed, the data may be amplified using a potential difference between the selected bit line BLT and the complementary bit line BLB. The read operation may be equally performed regardless of the level (logic high level or logic low level) of the data written in the memory cell.

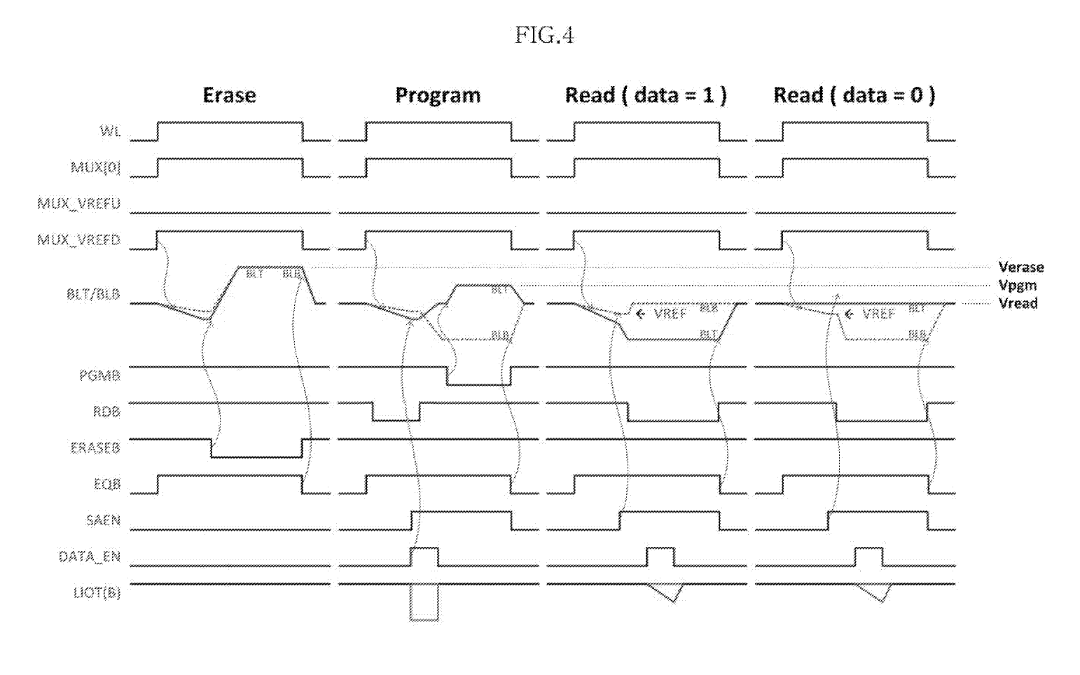

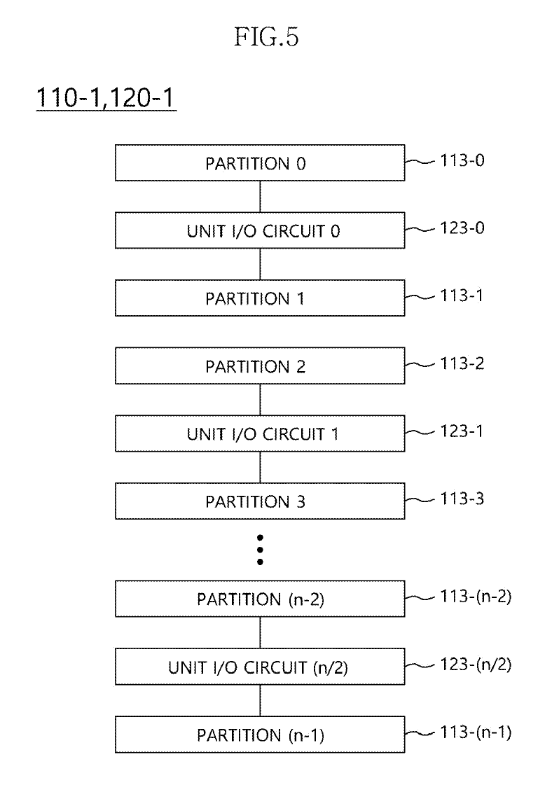

FIG. 5 is a diagram illustrating an example of a resistive memory apparatus according to an embodiment.

The resistive memory apparatus according to the embodiment may include a memory circuit 110-1 and an I/O circuit 120-1.

The memory circuit 110-1 may be divided into a plurality of partitions 113-0 to 113-(n-1), which may be collectively referred to as 113. Each of the partitions 113-0 to 113-(n-1) may include, for example, a plurality of memory cells arranged on intersections of a word line group including a plurality of word lines and a bit line group including a plurality of bit lines.

The I/O circuit 120-1 may include a plurality of unit I/O circuits 123-0 to 123-(n/2), which may be collectively referred to as “123.”

Each of the unit I/O circuits 123-0 to 123-(n/2) may be arranged between adjacent partitions 113 and each of the partitions 113 may be coupled to one unit I/O circuit 123.

The unit I/O circuit 123 may have the same configuration as those of the unit I/O circuits 121 and 20 illustrated in FIGS. 2 and 3.

During the I/O operation session for a certain partition 113, the operating voltage may be supplied through the unit I/O circuit 123 provided between a pair of partitions 113, and the read operation or the write operation may be performed.

In the resistive memory apparatus illustrated in FIG. 5, a size of the unit I/O circuit 123 may be minimized, and thus a size of the resistive memory apparatus may be further miniaturized.

FIG. 5 illustrates only the memory circuit 110-1 and the I/O circuit 120-1 of the resistive memory apparatus. Other peripheral circuits, for example, an I/O sense amplifier, a pad, a column selection circuit, a row selection circuit, a controller, and the like may be provided in a manner similar to those provided in FIG. 1.

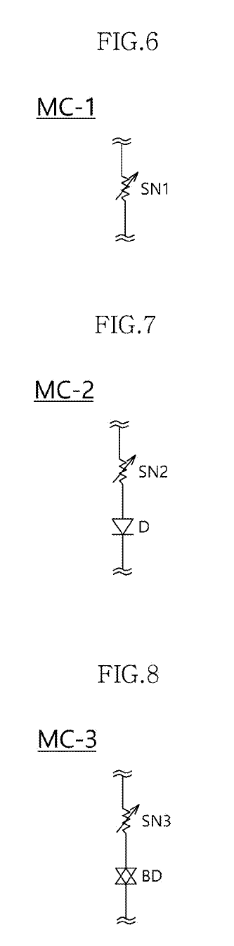

FIGS. 6 to 10 are diagrams illustrating resistive memory cells according to embodiments.

FIG. 6 illustrates an example of a memory cell MC-1 including, as a storage node SN1, a variable resistor arranged between a pair of wirings.

FIG. 7 illustrates an example of a memory cell MC-2 including a storage node SN2 and, as an access element, a diode D electrically coupled between a pair of wirings. In an embodiment, the diode D may be selected between a vertical channel transistor and a horizontal channel transistor.

FIG. 8 illustrates an example of a memory cell MC-3 including a storage node SN3 and, as an access element, a bi-directional diode BD electrically coupled between a pair of wirings.

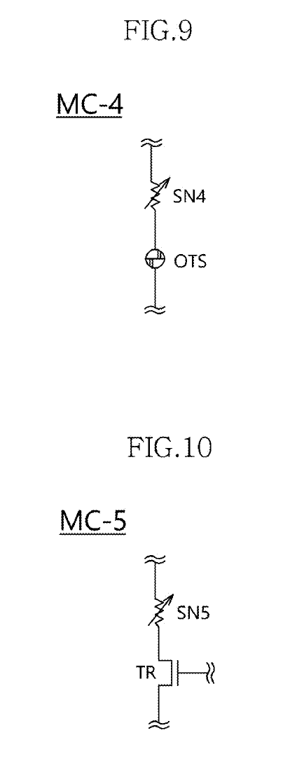

FIG. 9 illustrates an example of a memory cell MC-4 including a storage node SN4 and, as an access element, an ovonic threshold switching device OTS electrically coupled between a pair of wirings.

FIG. 10 illustrates an example of a memory cell MC-5 including a storage node SN5 and, as an access element, a transistor TR electrically coupled between a pair of wirings. In an embodiment, the transistor TR may be a MOS transistor such as a vertical channel transistor.

The storage nodes SN1 to SN5 in FIGS. 6 to 10 may be formed of a material that changes its resistance value according to an amount of applied current. The pair of wirings may include a word line and a bit line.

When the memory cell MC constituting the memory circuit 110 is accessed for the read or write operation, since a power supply circuit is provided for each partition, a stable operating voltage may be uniformly applied to the partition.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A resistive memory apparatus comprising:
a memory circuit divided into a plurality of partitions; and
a plurality of unit input/output (I/O) circuits each provided for each of the plurality of partitions, each I/O circuit being disposed where each partition is formed.

2. The resistive memory apparatus of claim 1, wherein each of the plurality of partitions is divided into an upper sub-partition including at least one word line and a lower sub-partition including at least one word line, and each of the plurality of unit I/O circuits is configured to be interposed between the upper sub-partition and the lower sub-partition of the partition.

3. The resistive memory apparatus of claim 2, wherein each unit I/O circuit arranged between the upper sub-partition and the lower sub-partition includes first and second selection circuits.

4. The resistive memory apparatus of claim 3, wherein the first selection circuit is assigned to the upper sub-partition to select one of bit lines of the upper sub-partition, and the second selection circuit is assigned to the lower sub-partition to select one of bit lines of the lower sub-partition.

5. The resistive memory apparatus of claim 1, wherein each of the plurality of partitions includes a plurality of resistive memory cells coupled between a plurality of word lines and a plurality of bit lines, and each of the plurality of unit I/O circuits is configured to supply a power voltage to a selected bit line of a partition corresponding thereto.

6. The resistive memory apparatus of claim 1, wherein each of the plurality of partitions includes a plurality of resistive memory cells coupled between a plurality of word lines and a plurality of bit lines, and each of the plurality of unit I/O circuits is configured to supply a read voltage, a first write voltage, and a second write voltage to a selected bit line of a partition corresponding thereto and output data signal by amplifying a voltage level of the data signal applied to the bit line in a read operation.

7. The resistive memory apparatus of claim 1, wherein the plurality of unit I/O circuits is coupled in common to an I/O sense amplifier.

8. A resistive memory apparatus comprising:
a memory circuit divided into a plurality of partitions; and
a plurality of unit input/output (I/O) circuits electrically coupled to an adjacent partition pair.

9. The resistive memory apparatus of claim 8, wherein each pair of partitions is coupled to a single unit I/O circuit.

10. The resistive memory apparatus of claim 8, wherein each of the plurality of unit I/O circuits is configured to be interposed between an adjacent partition pair.

11. The resistive memory apparatus of claim 10, wherein each unit I/O circuit arranged between the adjacent partition pair includes first and second selection circuits.

12. The resistive memory apparatus of claim 11, wherein the first selection circuit is configured to select one of bit lines of one of the adjacent partition pair, and the second selection circuit is configured to select one of bit lines of the other of the adjacent partition pair.

13. The resistive memory apparatus of claim 8, wherein each of the plurality of partitions includes a plurality of resistive memory cells coupled between at least one word line and a plurality of bit lines, and each of the plurality of unit I/O circuits is configured to supply a power voltage to a selected bit line of a partition corresponding thereto.

14. The resistive memory apparatus of claim 8, wherein each of the plurality of partitions includes a plurality of resistive memory cells coupled between at least one word line and a plurality of bit lines, and each of the plurality of unit I/O circuits is configured to supply a read voltage, a first write voltage, and a second write voltage to a selected bit line of a partition corresponding thereto and output data signal by amplifying a potential level of the data signal applied to the bit line in a read operation.

15. The resistive memory apparatus of claim 8, wherein each of the plurality of unit I/O circuits is coupled in common to an I/O sense amplifier.
